(19) United States
(12) Patent Application Publication
(10) Pub. No.: US 2015/0176147 A1
(43) Pub. Date: Jun. 25, 2015

(54) METHOD FOR FORMING A BODY COMPRISING A PARTICLE STRUCTURE FIXATED IN A MATRIX MATERIAL

(71) Applicant: INSTITUTT FOR ENERGITEKNIKK, Kjeller (NO)

(72) Inventors: Henrik Høyer, Skien (NO); Arne Torbørn Skjeltorp, Ski (NO); Mark Buchanan, Oslo (NO); Matti Knaapila, Drammen (NO); Geir Helgesen, Finstadjordet (NO)

(21) Appl. No.: 14/409,621

(22) PCT Filed: Jun. 25, 2013
(86) PCT No.: PCT/EP2013/063279

§ 371 Date: Dec. 19, 2014

(30) Foreign Application Priority Data
Jun. 25, 2012 (NO) 20120740

(51) Int. Cl. C25D 13/00; H05K 1/03; H05K 1/09

(52) U.S. Cl. CPC C25D 13/00; H05K 1/092; H05K 1/0353; H05K 2201/0272

(57) ABSTRACT

The invention relates to a method for forming a body comprising a particle structure fixated in a matrix material, comprising—Providing an amount of particles,—Providing a viscous matrix material to include said particles—Forming a particle structure of at least a portion of said amount of particles—Fixating said viscous matrix so as to fixate said particle structure in the matrix material characterised by at least a portion of said amount of particles being paramagnetic or ferromagnetic, and the formation of the particle structure includes the steps of: - Subjecting the particles to a first field, so as to arrange at least a portion of said particles into particle assemblies, each particle assembly comprising a plurality of particles and extending along a flux direction of said first field, and—Subjecting the particle assemblies to a second field, so as to move and/or rotate said particle assemblies along a flux direction of said second field,—wherein one of said first and second fields is a magnetic field, and the other of said first and second fields is an electric field, or a magnetic field having a different flux direction than said one magnetic field. The invention also relates to a body obtained by said method, and to the use of said method in various applications.

### TECHNICAL FIELD

The present invention relates to a method for forming a body comprising a particle structure fixated in a matrix material, comprising
Providing an amount of particles,
Providing a viscous matrix material to include said particles
Forming a particle structure of at least a portion of said amount of particles
Fixating said viscous matrix so as to fixate said particle structure in the matrix material.

The invention also relates to a body obtained by said method, and to the use of said method in various applications.

### BACKGROUND OF THE INVENTION

Anisotropic materials are used in a wide and increasing range of applications. Typically, such materials include conductive particles fixated in a non-conductive matrix material. The conductive particles are intended to form conductive pathways in the matrix material, so as to enable the anisotropic material to be, at least under certain circumstances, electrically conductive.

Depending on the selection of particles and matrix materials, the anisotropic materials may be formed to be suitable for various applications, such as for sensors, such as stress sensors, in solar cell applications, printed electronics etc.

Prior art methods for forming anisotropic materials often involve providing a viscous mixture including the matrix material and conductive particles, applying an electric field over the viscous mixture so as to cause the conductive particles to align to form conductive pathways in the mixture, and thereafter curing the viscous mixture.

Alternatively, it has been proposed to use the magnetic properties of the particles to cause the particles to align and to form conductive pathways. WO 2008/153679 is such an example, where a viscoplastic material including a plurality of magnetic particles is subject to a magnetic field for a time sufficient to at least partially align a portion of the magnetic particles to a predetermined position.

To increase the versatility of the anisotropic materials formed, and to enable industrial production thereof, there is a need for alternative methods for forming materials in this field.

It is an object of the invention to provide a method fulfilling said need.

### SUMMARY OF THE INVENTION

The above-mentioned object is achieved by a method for forming a body comprising a particle structure fixated in a matrix material, comprising

providing an amount of particles,

providing a viscous matrix material to include said particles,

forming a particle structure of at least a portion of said amount of particles, and

fixating said viscous matrix so as to fixate said particle structure in the matrix material.

In accordance with the proposed method, at least a portion of said amount of particles being paramagnetic or ferromagnetic, and

the formation of the particle structure includes the steps of:
Subjecting the particles to a first field, so as to arrange at least a portion of said particles into particle assemblies, each particle assembly comprising a plurality of particles and extending along a flux direction of said first field, and
Subjecting the particle assemblies to a second field, so as to move and/or rotate said particle assemblies along a flux direction of said second field,

wherein one of said first and second fields is a magnetic field, and the other of said first and second fields is an electric field, or a magnetic field having a different flux direction than said one magnetic field.

With “particle assembly” is meant herein a plurality of particles that have gathered under the influence of a first field. The particle assemblies will have a generally elongate configuration with an extension along the flux direction of said first field. For example, the particle assemblies may have the form of strings extending in the flux direction of the first field.

In accordance with the proposed method, the particle assemblies are formed under the influence of a first field. Thereafter, the particle assemblies are subject to a second field, which will have the effect of moving and/or rotating the particle assemblies.

With “particle structure” is meant herein any desired configuration or structure of particles which is or is to be fixated in matrix material.

In accordance with the proposed method, the particle structure is achieved only after the particle assemblies have been subject to the second field, moving and/or rotating the particle assemblies.

The particle structure, which is to be fixated in the matrix material, may be achieved directly by the two steps described in the above—the creation of particle assemblies by a first field and the subsequent moving and/or rotating of the particle assemblies by a second field will hence immediately result in the particle structure to be fixated.

However, it is also possible to add additional fields for creating particle assemblies and/or for moving and/or rotating particle assemblies, in order to attain the desired particle structure. Hence, the particle assemblies could be subject to a third field, a fourth field and so on. Moreover, the first and second field as described in the above may be alternately applied to achieve a final particle structure.

In an embodiment, the other of said first and second fields is an electric field, and at least a portion of said amount of particles is electrically conductive. This embodiment has the advantage that the particle structure may include an electrically conductive pathway formed by the electrically conductive particles.

Advantageously, said first field may be a magnetic field.

In accordance with one embodiment of the method, the formation of the particle structure includes:
First, the particles are provided separate from the matrix material,
Second, the particles are subject to the first field so as to form the particle assemblies,
Third, the viscous matrix material is applied to the particle assemblies,
Fourth, the particle assemblies are subject to the second field so as to move and/or rotate the particle assemblies in the viscous matrix material.

In this embodiment, the particle assemblies are obtained by letting the particles be subject to a first field, typically a magnetic field. Thereafter, viscous matrix material is applied to the particle assemblies. For example, the matrix material may be poured over the particle assemblies. Thereafter, the viscous matrix material including the particle assemblies is subject to a second field. The second field may be a magnetic or an electric field. Under the influence of the second field, the particle assemblies may be moved and/or rotated in the matrix material.

In another embodiment, the formation of the particle structure includes:
First, the particles are provided in a mixture with the viscous matrix material,
Second, the viscous mixture is subject to the first field is to form the particle assemblies in the viscous matrix material,
Third, the viscous mixture with the particle assemblies is subject to the second field so as to move and/or rotate the particle assemblies in the viscous matrix material,

In one embodiment of the invention the rotation of the particle assemblies upon application of the second field may be 90 degrees.

In this embodiment, the particles are initially provided in a mixture with the viscous matrix material, and are subject to a first field to form the particle assemblies. The first field could be a magnetic or an electric field. Thereafter, a second field is applied to the viscous mixture, so as to move and/or rotate the particle assemblies.

Advantageously, the method may be used so as to form a particle structure including at least one pathway of particles extending through the matrix material. A pathway extending through the matrix material is such that the ends of said pathway may be connected to external devices. Preferably at least a portion of said particles are conductive such that the pathway is a conductive pathway. The method is hence suitable for forming a body having a conductive pathway through a matrix material, which may in turn have uses e.g. as a sensor.

Preferably, the magnetic field, or at least one of said magnetic fields, is created by an open Kittel structure, comprising two magnets being arranged with opposite directions of the polarity of their magnetic field, and wherein a junction is formed at the mating faces of said two magnets.

It has been found, that an open Kittel structure is particularly useful for providing suitable magnetic fields and field gradients for use with the proposed method.

An open Kittel structure may provide magnetic fields having relatively large separation strengths.

With “separation strength” is meant herein the product B VB, where B is the magnetic induction and VB is the gradient of the magnetic field. In prior art, focus has often been on the size of the magnetic flux. However, it has been understood that the separation strength may have a greater impact on the capacity of the field to displace particles, in particular when mixed in a viscous matrix material. Using a magnetic field with relatively high separation strength will moreover enable relatively fast displacement of the particles.

As speed is an important factor when it comes to enabling industrial production using the proposed method, the use of a field having a relatively large separation strength, e.g. from an open Kittel structure, may be a key factor to succeeding with industrial applications.

The time periods required for magnetic alignment depend on factors like the thickness of the sample, the viscosity of the polymer matrix and the susceptibilities of the magnetic particles. For example, advantageously the particles may be subject to the first magnetic field for a time period being less than 5 s, preferably less than 3 s, most preferred less than 1 s to form said particle assemblies. Using a magnetic field from an open Kittel structure may be advantageous to enable formation of particle assemblies in time periods being less than 5 s, preferably less than 3 s, most preferred less than 1 s.

Although it is possible to estimate the separation strength of the magnetic field from an open Kittel structure, it is difficult to determine exact values thereof. Various analytic calculations of the separation strengths have been attempted, but no conclusive method is available. Moreover, practical measurements are also difficult to perform. However, to give an idea of what is a relatively high separation strength, it may be referred to works from Il'yashenko et al. in Phys. Stat. Sol. (a) 203, No. 7, 1556-1560 (2006), suggesting a separation strength of 4.2˜10⁵ T²/m, or by Inge B. Roth in master thesis, University of Oslo, May 2009, instead arriving at 5˜10⁴ T²/m, both at a distance of 10 μm above the mask of an open Kittel structure as generally described in EP 1 842 596.

Moreover, an open Kittel structure may be advantageous in that the particles to be subject to the field may conveniently be arranged above the junction of the Kittel structure. Preferably, the particles shall be positioned close to said junction, for example the particles may be positioned at a distance form said junction being less than 3 mm, preferably less than 1 mm, most preferred less than 0.5 mm.

Advantageously, the open Kittel structure may be provided with a mask arranged over the two magnets, said mask having a gap corresponding to the junction of the open Kittel structure.

When an open Kittel structure is used, and when said magnetic field is the first field, the particle assemblies are advantageously formed so as to at least partially bridge the junction of the Kittel structure. For example, the particle assemblies could have the form of strings extending over the junction of the Kittel structure.

When the particles are in a viscous mixture with the viscous matrix material, it is preferred that the particles have a concentration in the viscous matrix material being less than the percolation threshold.

For conductive mixtures a “percolation threshold” is defined as the lowest concentration of conductive particles necessary to achieve long-range conductivity in the random system.

Such a random system is nearly isotropic. In a system formed by a method according to the invention the concentration of conductive particles necessary for achieving conductivity in a predefined direction is not determined by the percolation threshold and the concentration can be lower. For practical reasons the concentration of particles is determined by the requirements on the conductive paths, there usually being no reason to have excess amounts of conductive particles not arranged into the conductive paths.

The concentration of particles in the viscous matrix could be up to 10 times lower than the percolation threshold or even lower. Concentrations of particles may be in the range of 0.01-10 vol %, or 0.01-2 vol %, or 0.01-1.5 vol

For example, the particles may have a concentration in the viscous matrix material in the range 0.01 to 1 vol.

To be displaceable by use of a magnetic field, the particles may advantageously be paramagnetic of ferromagnetic, preferably ferromagnetic.

To be displaceable by use of an electric field, the particles may advantageously be electrically conductive and/or being made of one or more materials having a dielectric constant that is much smaller or much larger than that of the matrix.

The particles may be homogenous particles, i.e. a particle consists of a single material or material mixture throughout the particle. However, the particles may also be heterogeneous particles, i.e. a particle consists of several materials, for example the particle may have a core of one material, and a sheath of another material.

The particles to be subject of the fields in the proposed method may comprise only one type of particles, but may also be a mixture of different types of particles. Particles may be para-/ferromagnetic and/or electrically conductive.

Advantageously, at least some particles may be both para- or ferro magnetic, and electrically conductive. Alternatively, there may be a mixture of paramagnetic or ferromagnetic particles. Such particles will be displaceable by both magnetic and electric fields.

Advantageously, the amount of particles includes particles of metal and/or metal alloys, preferably nickel or iron oxide.

The size of the particles, i.e. the largest linear dimension of the particles, may advantageously be in the range 10 nm to 100 μm.

Electric fields used with the method may advantageously have a field strength in the range of 1-20 kV/cm; preferably 5-15 kV/cm. The electric field may advantageously be an alternating field, preferably having a frequency in the range 10 Hz to 10 MHz, most preferred 0.1 kHz to 10 kHz.

The matrix material should be material having a viscous form which is capable of being fixed. Fixation may be achieved by any suitable method, such as, for example, cooling, curing, ceramisation, cross-linking, gelling, irradiating, drying, heating, sintering, or firing.

Advantageously, the matrix material comprises a polymer material.

In particularly useful embodiments, the viscous matrix material may be UV-curable, and the fixating of the matrix material comprises UV curing thereof.

In other useful embodiments, the viscous matrix material may be humidity-curing, and the fixating of the matrix material comprises exposing the mixture to moisture, preferably in air at room temperature.

Advantageously the matrix material, when fixated, is an elastomeric material. This enables creation of bodies being useful for applications such as strain sensors, where the elastic properties of the matrix material is used together with the properties of the particle structure to achieve a desired function.

In another aspect, the invention relates to a method for forming a body having a plurality of layers comprising particle structure fixated in matrix material, wherein at least one of said layers is formed by the method as proposed herein.

Advantageously, the matrix material of said at least one layer may be reduced before formation of another layer of the multi-layered structure thereupon.

Advantageously, in said method for forming a body having a plurality of layers, at least one layer may be formed by printing conductive pathways using one out of screen printing, and inkjet coating.

Advantageously, in said method for forming a body having a plurality of layers, at least two layers are formed by the method as proposed herein.

In another aspect, the invention relates to a body comprising a particle structure fixated in a matrix material, wherein said body is formed by the method in accordance with the invention.

In another aspect, it is proposed the use of a method in accordance with the invention for creating printed electronics.

In another aspect, it is proposed the use of a method in accordance with the invention for creating RF shielding.

In another aspect, it proposed the use of a method in accordance with the invention, for creating transistors.

In another aspect, it is proposed the use of a method in accordance with the invention for creating three dimensional geometries of conductive pathways.

Advantageously, the particle structure may comprise conductive pathways.

### BRIEF DESCRIPTION OF THE DRAWINGS

The invention will now be further described with reference to exemplary embodiments, with reference to the enclosed drawings, wherein:

FIG. 1 is a schematic illustration of an embodiment of an open Kittel structure with mask;

FIGS. 2a-2b are micrographs showing the alignment of particles in a viscous matrix in accordance with an embodiment of the invention.

FIGS. 3a-3b are photographs illustrating a conductive pathway of particles formed in accordance with another embodiment of the invention.

### DETAILED DESCRIPTION OF PREFERRED EMBODIMENTS

As mentioned in the above, a magnetic field created by an open Kittel structure wherein a junction is formed between the two magnets, may advantageously be used with the present invention.

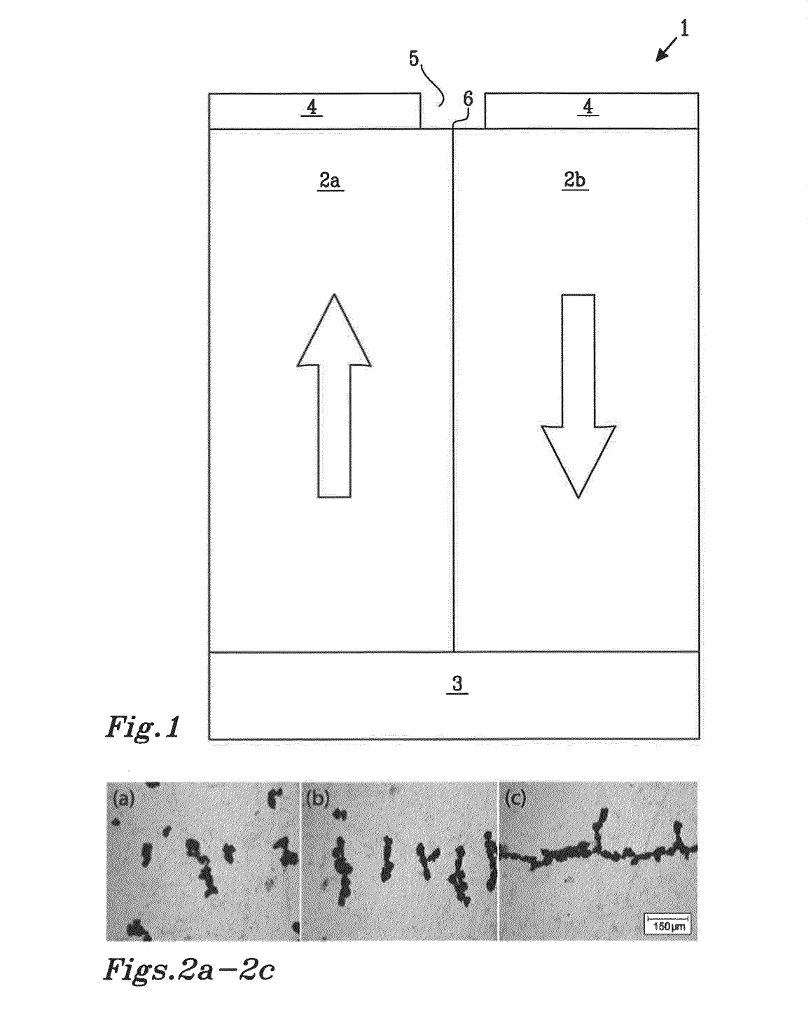

A similar magnet system is schematically illustrated in FIG. 1. The magnetic system 1 comprises one permanent magnet 2a with polarisation in a first direction (up) and another permanent magnet 2b with polarisation in a direction opposite to the first direction (down). The magnets 2a, 2b are joined together along adjacent surfaces, forming a junction 6 between the magnets 2a, 2b. Moreover, the magnets 2a, 2b are mounted on a base of magnetic material, the yoke 3.0n top of both magnets is mounted a thin plate of high permeability magnetic material (e.g. permendure, permalloy, etc.), denoted the “mask” 4.

A thin gap 5 is formed between the portions of the mask 4 covering the “up” magnet 2a and the “down” magnet 2b, the location of the gap 5 corresponding to the junction 6 between the adjacent surfaces of the up and down magnets 2a, 2b.

The purpose of the mask 4 is to collect the magnetic flux lines and steer them toward the gap 5 where both the flux and the flux gradient will be very high. Typically, the size of the gap 5 would be of a size approximately corresponding to the thickness of the mask 4.

FIGS. 2a-2c illustrate particles in a viscous matrix during the performance of an embodiment of a method in accordance with the invention.

FIG. 2a is a micrograph of the particles being initially dispersed in a viscous polymer. The particles are then subject of a first field being a magnetic field.

FIG. 2b is a micrograph of the particles dispersed in the viscous polymer after being subject to said first field. It is seen how the particles have gathered into particle assemblies, in this case in the form of several strings. The particle assembles were then subject of a second field being an electric field.

FIG. 2c is a micrograph of the particles dispersed in the viscous polymer after being subject also to said second field. It is seen how the particle assemblies, the strings, have rotated about 90 degrees and connected to each other. The connected particle assemblies form a pathway through the sample. The particles being conductive, the pathway is a conductive pathway, which extends through the matrix material.

In the illustrated embodiment, the electric field was an AC field having a strength of about 100 V/cm, namely a square wave with a frequency of 20 kHz.

Hence, it is demonstrated that a conductive pathway may be formed by particles in a mixture with a viscous matrix material in accordance with an embodiment of the invention.

In another embodiment, particles were first subject to a first field, being a magnetic field from an open Kittel structure as the one described in the above.

The particles were then assembled into particle assemblies in the form of strings, similar to those depicted in FIG. 2b, but with no surrounding viscous matrix.

Thereafter, viscous matrix material was poured on top of the particle assemblies in such a way that all the particles were completely covered by the polymer.

Thereafter, the particle assemblies were subject to a second field, being an electric field, rotating the particle assemblies so as to connect them into a particle structure being a conductive pathway.

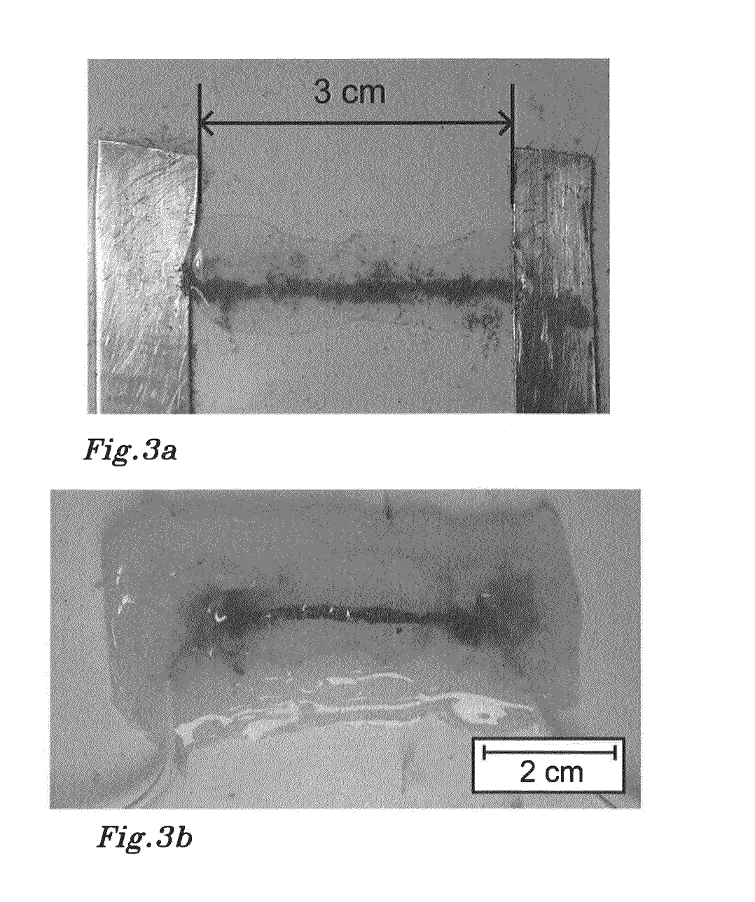

FIG. 3a illustrates the particle structure being a conductive pathway under the layer of viscous matrix material.

The viscous matrix material was then fixated such that the particle structure was also fixated under the matrix material layer.

In this case, a second viscous matrix material was then applied to protect the particle structure. Moreover, electrodes were connected to the particle structure (i.e. the conductive pathway) so as to form a sample useful as a sensor after fixation of the second viscous matrix material.

FIG. 3b illustrates the conductive pathway when connected to electrodes and surrounded by the second matrix material. The sample thus obtained had a spacing of 3 cm between the electrodes, which were connected to wires sticking out at the bottom of the sample.

The particles used in this example were nickel coated graphite particles, which are electrical conductive particles. The particular type of particles used was particle type 2702 from Sulzer. These particles are ferromagnetic.

The first matrix material poured on top of the particle assemblies was Dow Corning 10 SE9187 L. This is an elastomer with a relatively low viscosity.

The second matrix material applied to protect the particle structure was Dow Corning 734, which is a silicone with a relatively high viscosity which cures to a flexible rubber.

Both matrix materials cure in room temperature when exposed to moisture in the air.

The sample obtained by the above-mentioned method was subject to some tests. The electrical resistance through the sample when relaxed was about 170 Ohm. The sample was then deflected, which resulted in a dramatic increase in resistance. In fact, the resistance of the sample when deflected about 0.5 cm in the vertical direction was greater than 120 MOhm (being the limit of the Keithly 2000 multimeter used).

When the sample was relaxed, the resistance was again decreased and reached its original value of 170 Ohm. In a further test, the sample was stretched. The resistance of the sample was 700 Ohm before stretching. The resistance increased to 1.5 kOhm when the sample was stretched 500 μm. Increasing the stretching distance to 1 mm increased the resistance to about 3 kOhm. Further stretching of the sample to 2 mm resulted in an increase to about 4 kOhm. The sample was finally stretched to 2.5 mm resulting in a value greater than 120 MOhm (being the limit of the Keithly 2000 multimeter used). Relaxing the sample from 2.5 to 2 mm decreased the resistance to about 4 kOhm. Relaxing the sample 30 to 0 mm resulted in a decrease in resistance to about 700 Ohm. Thus, the resistance values increase from 700 Ohm to over 120 MOhm when a strain of about 8% is applied. This makes the material of the sample useful as a sensor. Accordingly, it is possible to produce a flexible and sensitive strain sensor by combining alignment using a magnetic field and an electric field.

### Single Field vs Two Fields

The bodies created using the methods as proposed herein may moreover present additional advantages and different properties as compared to those obtained using prior art methods, in which only a single field is used.

Ni coated graphite particles were used in all samples below.
Electric Field Only vs Magnetic and Electric Field For preparation of a first sample, a pair of electrodes was arranged with a spacing of 3 cm. A viscous matrix material, the polymer Dymax 3094, was first applied between the electrodes. The nickel coated graphite particles were then mixed with the polymer such that the particles were uniformly dispersed between the electrodes. The particle fraction was fairly low, in the 0.1 vol % range. An electric field was applied over the electrodes, in this case an alternating field in a square wave, and with a frequency of 20 kHz.

First, the field strength was about 100 V/cm, and applied for one minute. This had no effect on the particles.

The field strength was then set to about 230 V/cm, which did have an effect on the particles. For the particles to form a particle structure in the form of a conductive pathway between the electrodes, the electric field of 230 V/cm was applied for about 30 s. Hence, this first sample was prepared using an electrical field only, in accordance with prior art technology.

For preparation of a second sample, the same particles and particle concentration in the same viscous matrix was used. The particles were first subject to a magnetic field from an open Kittel structure as the one described above. This caused the particles to form a plurality of particle assemblies extending in parallel.

Thereafter, the particle assemblies were subject to an electric field.

The field strength of the electric field was 100 V/cm. This had the effect of rotating the particle assemblies so as to interconnect and form a conductive pathway in the matrix material. For forming the pathway, the field of 100 V/cm was applied for about 15 s.

Hence, in view of the above, it is understood that the first field is indeed of importance when forming the particle structure of the second sample. Lower voltages and less time are needed to get alignment of the particles when they have first been aligned using a magnetic field.
Magnetic Field Only vs Magnetic and Electric Field

A first sample was prepared by nickel coated graphite particles arranged between two electrodes with a spacing of 4.5 cm, and the particles then being subject to a magnetic field from an open Kittel structure as the one described in the above. A relatively large amount of particles were used, and the magnetic field applied for a time sufficient for the particles to form a particle structure in the form of a conductive pathway between the electrodes.

Such a pathway could, in this context be described as the result of particle assemblies being created having the form of parallel strings, where there are so many strings that they come into contact with one another. The parallel strings will hence form a pathway, said pathway having an extension perpendicular to the strings.

A viscous matrix, namely Dow Corning SE9187 was poured over the particle structure.

The electrical resistance between the electrodes was measured during the curing process of the matrix material.

Resistance values:

Just after formation: >120 MOhm

After three days: ˜50 MOhm

After four days: ˜1.5 MOhm

After five days: ˜5 kOhm

Hence, the electrical resistance of the first sample decreases from a value that was above 120 MOhm right after the preparation to about 5 kOhm five days later, This shows that the curing process continues for at least 5 days and that the curing increases the connection between the particles.

For preparation of the second sample, the same type of particles were again aligned using a open Kittel structure, as the one used for the first sample. A pair of electrodes was arranged with a spacing of 3 cm. In this case, the particle concentration was relatively low, such that, when the magnetic field was applied, particle assemblies in the form of parallel strings being located separately from each other were created. The same matrix material as the one used for the first sample was poured over the particle assemblies. Then, an alternating electric field was applied over the electrodes. The field was a square wave with a frequency of 20 kHz and voltage of about 70 V/cm. The field was applied for about 5 minutes, resulting in the particle assemblies being rotated to form an electrically conductive pathway between the electrodes.

Again, the resistance values during curing of the matrix material were measured. In this case, the resistance just after preparation was found to be 120 Ohm, and the resistance after five days, was also 120 Ohm.

Hence, the resistance value of the second sample was not influenced by the curing process. Moreover, the resistance of the pathway of the second sample was much lower than the resistance of the pathway of the first sample.

Accordingly, the method as proposed herein may be used to provide bodies having different properties than those prepared in accordance with prior art methods.

It should be noted that the described features of the various embodiments may be combined with each other. Accordingly, no embodiment is intended to limit any combination of features which are presented in the embodiments, but rather to illustrate examples of embodiments.

1. A method for forming a body comprising a particle structure fixated in a matrix material, comprising:
Providing an amount of particles, at least a portion of the amount of particles being paramagnetic or ferromagnetic;
Providing a viscous matrix material to include said particles;
Forming a particle structure of at least a portion of said amount of particles;
Fixating said viscous matrix so as to fixate said particle structure in the matrix material,
the formation of the particle structure including the steps of:
Subjecting the particles to a first field, so as to arrange at least a portion of said particles into particle assemblies, each particle assembly comprising a plurality of particles and extending along a flux direction of said first field, and
Subjecting the particle assemblies to a second field, so as to at least one of move and/or rotate said particle assemblies along a flux direction of said second field, one of the first field and the second field being a first magnetic field and the other of the first field and the second field being one of an electric field and a second magnetic field having a different flux direction than the first magnetic field.

2. The method according to claim 1, wherein at least one of the first and second fields is an electric field, and at least a portion of said amount of particles is electrically conductive.

3. The method according to claim 1, wherein said first field is a magnetic field.

4. The method according to claim 3, wherein the formation of the particle structures includes the steps of:
providing the particles separate from the matrix material;
subjecting the particles to the first field so as to form the particle assemblies;
applying the viscous matrix material to the particle assemblies; and
subjecting the particle assemblies to the second field so as to at least one of move and rotate the particle assemblies in the viscous matrix material.

5. The method according to claim 1, wherein the formation of the particle structures includes the steps of:
providing the particles in a mixture with the viscous matrix material;
subjecting the viscous mixture to the first field to form the particle assemblies in the viscous matrix material; and
subjecting the viscous mixture with the particle assemblies to the second field so as to at least one of move and rotate the particle assemblies in the viscous matrix material.

6. The method according to claim 1, wherein the particle structure includes at least one pathway of particles extending through the matrix material, at least a portion of the particles being conductive such that the pathway is a conductive pathway.

7. The method according to claim 1, wherein the magnetic field, or at least one of the magnetic fields, is created by an open Kittel structure, comprising two magnets arranged with opposite directions of the polarity of their magnetic field, and wherein a junction is formed at the mating faces of the two magnets.

8. The method according to claim 7, wherein, when the magnetic field is the first field, the particle assemblies are formed so as to at least partially bridge the junction of the Kittel structure.

9. The method according to claim 1, wherein the particles have a concentration in the viscous matrix material being less than the percolation threshold.

10. The method according to claim 1, wherein the particles have a concentration in the viscous matrix material in the range of 0.01 to 1 vol %.

11. The method according to claim 1, wherein the amount of particles includes particles of at least one of metal and metal alloys, preferably nickel or iron oxide.

12. The method according to claim 1, wherein the size of the particles is in the range of 10 nm to 100 μm.

13. The method according to claim 1, wherein the particles are subject to the first field for a time period being less than 5s, preferably less than 3s, most preferred less than 1s to form said particle assemblies.

14. The method according to claim 1, wherein the other field is an electric field having a field strength in the range of 1-20 kV/cm, preferably 5-15 kV/cm.

15. The method according to claim 1, wherein the other field is an electric field being an alternating field, preferably having a frequency in the range 10 Hz to 10 HMz, most preferred 0.1 kHz to 10 kHz.

16. The method according to claim 1, wherein the matrix material comprises a polymer material.

17. The method according to claim 1, wherein the viscous matrix material is UV-curable, and the fixating of the matrix material comprises UV curing thereof.

18. The method according to claim 1, wherein the matrix material, when fixated, is an elastomeric material.

19. method for forming a body having a plurality of layers comprising particles structure fixated in matrix material, wherein at least one of the layers is formed by the method of claim 1.

20. A method for forming a body having a plurality of layers in accordance with claim 19, wherein the matrix material of the at least one layer is reduced before the formation of another layer of the multi-layered structure thereupon.

21. A method for forming a body having a plurality of layers in accordance with claim 19, wherein at least one layer is formed by printing conductive pathways using one out of screen printing and inkjet coating.

22. A method for forming a body having a plurality of layers comprising particles structure fixated in matrix material, wherein at least two of the layers are formed by the method in accordance with claim 1.

23. A body comprising particle structure fixated in a matrix material, wherein said the body is formed by the method in accordance with claim 1.

24. A multi-layered body comprising particle structure forming at least one conductive pathway, wherein the body is formed by the method in accordance with the claim 21.

25. Use of a method in accordance with claim 1 for creating printed electronics.

26. Use of a method in accordance with claim 1 for creating RF shielding.

27. Use of a method in accordance with claim 1 for creating transistors.

28. Use of a method in accordance with claim 1 for creating three dimensional geometries of conductive pathways.
